(19) United States
(12) Patent Application Publication
(10) Pub. No.: US 2022/0199873 A1
(43) Pub. Date: Jun. 23, 2022

(54) OPTOELECTRONIC COMPONENT AND METHOD FOR PRODUCING AN OPTOELECTRONIC COMPONENT

(71) Applicant: OSRAM Opto Semiconductors GmbH, Regensburg (DE)

(72) Inventors: Matthias GOLDBACH, Pentling (DE); Andreas DOBNER, Wenzenbach (DE)

(21) Appl. No.: 17/432,407

(22) PCT Filed: Feb. 13, 2020
(86) PCT No.: PCT/EP2020/053787

§ 371 Date: Aug. 19, 2021

(30) Foreign Application Priority Data
Feb. 21, 2019 (DE) 102019104436.7

(51) Int. Cl. H01L 33/62; H01L 31/02

(52) U.S. Cl. CPC H01L 33/62; H01L 2933/0066; H01L 31/02005

(57) ABSTRACT

An optoelectronic component is specified, with an optoelectronic semiconductor chip which, in operation, is configured to emit or detect electromagnetic radiation, a connection carrier, on which the semiconductor chip is arranged, an electrically conductive connection, which is electrically conductively connected to the semiconductor chip and/or the connection carrier, and an electrically insulating material, which surrounds the semiconductor chip and/or the connection carrier at least in places, wherein the electrically conductive connection is arranged in places on the electrically insulating material. Furthermore, a method for producing an optoelectronic component is specified.

An optoelectronic component is specified. Furthermore, a method for producing an optoelectronic component is specified.

An object to be solved is to specify an optoelectronic component, which is particularly compact. Another object to be solved is to specify a method for producing such an optoelectronic component.

According to at least one embodiment, the optoelectronic component comprises an optoelectronic semiconductor chip, which is configured to emit or detect electromagnetic radiation during operation. The radiation emitted during operation of the semiconductor chip can be, for example, near-ultraviolet radiation, visible light and/or near-infrared radiation. Alternatively, it is possible that the electromagnetic radiation detected during operation of the semiconductor chip is near-ultraviolet radiation, visible light and/or near-infrared radiation.

If the optoelectronic semiconductor chip is a radiation-emitting semiconductor chip, the semiconductor chip is, for example, a light-emitting diode chip or a laser diode chip. If the optoelectronic semiconductor chip is a radiation-detecting semiconductor chip, the optoelectronic semiconductor chip is, for example, a photodetector.

In particular, the optoelectronic semiconductor chip comprises a bottom surface, which extends in lateral directions and which faces a top surface of the optoelectronic semiconductor chip. The bottom surface and the top surface are connected to one another by at least one side surface. For example, the bottom surface of the semiconductor chip and the top surface of the semiconductor chip each have a chip contact surface which are configured to be electrically contactable. In other words, the chip contact surfaces on the bottom surface of the semiconductor chip and on the top surface of the semiconductor chip are electrically conductively contacted in order to apply current to the semiconductor chip.

Alternatively, it is possible that the optoelectronic semiconductor chip is a flip chip, for example. This has, for example, two chip contact surfaces. The chip contact regions are arranged on the bottom surface of the semiconductor chip, for example. In this case, the chip contact regions are electrically conductively contacted on the bottom surface for energizing the semiconductor chip.

For example, it is possible that the optoelectronic component comprises a plurality of optoelectronic semiconductor chips. In this case, the semiconductor chips are configured to emit or to detect electromagnetic radiation during operation. The electromagnetic radiation emitted or detected by different semiconductor chips can be, for example, light of different colours. For example, the semiconductor chips can be configured to emit or detect light of red, yellow, green or blue colour.

According to at least one embodiment, the optoelectronic component comprises a connection carrier, on which the semiconductor chip is arranged. The semiconductor chip is, for example, electrically conductively connected to the connection carrier. The connection carrier has, for example, a main extension plane. Lateral directions are preferably aligned parallel to the main extension plane and a vertical direction is aligned perpendicular to the lateral direction. The connection carrier and the semiconductor chip are stacked, for example, in a vertical direction above one another. For example, the semiconductor chip has an extent in lateral directions that is smaller than an extent in lateral directions of the connection carrier. For example, the semiconductor chip and the connection carrier completely overlap in plan view.

If the optoelectronic component has the plurality of semiconductor chips, the semiconductor chips are arranged on the connection carrier, for example. The semiconductor chips overlap with the connection carrier, for example completely. The semiconductor chips are arranged on the connection carrier, for example, in a matrix-like manner, i.e. along columns and rows. The semiconductor chips are arranged at grid points of a regular grid, for example. The regular grid can be a triangular grid, a square grid, a hexagonal grid or a polygonal grid.

The semiconductor chips are arranged, for example, laterally spaced apart from one another.

The connection carrier comprises, for example, a base body comprising a semiconductor material or a ceramic material. For example, the semiconductor material comprises silicon and/or gallium nitride. Further, the connection carrier can comprise an electrically conductive metal embedded in the base body of the connection carrier and/or applied to the base body. “Embedded” in this context can mean that the electrically conductive metal abuts on the base body, lies partially or completely within the base body, and/or is enclosed by the base body on at least a portion of its otherwise exposed outer surface. In this case, the electrically conductive metal can be in direct immediate contact with the base body.

According to at least one embodiment, the optoelectronic component comprises an electrically conductive connection, which is electrically conductively connected to the semiconductor chip and/or the connection carrier. For example, the electrically conductive connection is in direct contact with the semiconductor chip. Furthermore, the electrically conductive connection can be in direct contact with the connection carrier. For example, the electrically conductive connection is formed with a metal or an electrically conductive adhesive. Furthermore, the electrically conductive interconnect can comprise a combination of several metals.

The electrically conductive connection has, for example, a height in the vertical direction that is between at least 1 μm and at most 15 μm. The height of the electrically conductive connection is, within the producing tolerance, in particular constant over an entire extent of the electrically conductive connection. The electrically conductive connection has, for example, a width in lateral directions that is comparatively large compared to the height of the electrically conductive connection. The width of the electrically conductive connection can, for example, be greater than the height of the electrically conductive connection by a factor of 10 or 100 or 1000.

For example, it is possible for the optoelectronic component to have a plurality of electrically conductive connections. In particular, the component has a plurality of electrically conductive connections when the component comprises the plurality of semiconductor chips. In this case, the electrically conductive connections electrically conductively interconnect the semiconductor chips and/or the connection carrier.

At least one of the electrically conductive connections has, for example, a first mounting surface for the semiconductor chip. In the region of the first mounting surface, the electrically conductive connection can, for example, have an increased extent in lateral directions. That is, the width of the electrically conductive connection in the region of the first mounting surface is greater than the width of the electrically conductive connection, for example, in a region above the electrically insulating material. For example, if the component has a plurality of semiconductor chips, the first mounting surface provides a mounting surface for all of the semiconductor chips.

Alternatively, at least two of the electrically conductive connections can form a second mounting surface for a semiconductor chip. In the region of the second mounting surface, the associated electrically conductive connections do not have an increased extent in lateral directions. In this case, the optoelectronic semiconductor chip is, for example, a flip chip. The chip contact surfaces are each electrically conductively contacted by an electrically conductive connection, for example.

If the component has a plurality of semiconductor chips, at least two of the electrically conductive connections in the region of the second mounting surface constitute a mounting surface for one semiconductor chip each.

According to at least one embodiment, the optoelectronic component comprises an electrically insulating material, which surrounds the semiconductor chip and/or the connection carrier at least in places. The electrically insulating material can be transparent, reflective, in particular diffusely reflective, or absorbent for the radiation emitted or detected by the semiconductor chip. The electrically insulating material is formed with a matrix material, for example. The matrix material is formed, for example, from a plastic, such as a silicone, an epoxy or an epoxy hybrid material.

A colouring agent such as carbon black or a pigment can be added to the matrix material. Thus, the electrically insulating material can appear black, or white or coloured. Alternatively or additionally, particles, in particular light-reflecting and/or light-scattering particles, can be incorporated into the matrix material, for example. For example, the particles comprise or contain at least one of the following materials: TiO₂, BaSO₄, CnO, AlₓO_{y}.

For example, side surfaces of the connection carrier are completely covered by the electrically insulating material. For example, a top surface of the connection carrier terminates flush with the electrically insulating material.

Furthermore, it is possible that side surfaces of the semiconductor chip are completely covered by the electrically insulating material. For example, the electrically insulating material terminates flush or planar with a top surface of the semiconductor chip. If the optoelectronic component has the plurality of semiconductor chips, the electrically insulating material completely covers all side surfaces of the semiconductor chips.

According to at least one embodiment, the electrically conductive connection is arranged in places on the electrically insulating material. For example, the electrically conductive connection is in direct contact with the electrically insulating material in places and covers the outer surface thereof in places.

In at least one embodiment, the optoelectronic component comprises:
an optoelectronic semiconductor chip which, in operation, is configured to emit or detect electromagnetic radiation,
a connection carrier, on which the semiconductor chip is arranged,
an electrically conductive connection, which is electrically conductively connected to the semiconductor chip and/or the connection carrier, and
an electrically insulating material, which surrounds the semiconductor chip and/or the connection carrier at least in places, wherein
the electrically conductive connection is arranged in places on the electrically insulating material.

The optoelectronic component described herein now makes use, inter alia, of the idea that the semiconductor chip is arranged on a connection carrier. Such an arrangement allows the component to have a height in the vertical direction, which is particularly small, for example at most 0.45 mm. Furthermore, the component can thus be particularly compact in lateral directions and have, for example, a length and a width of at most 2.5 mm each, in particular at most 2.2 mm. By arranging the semiconductor chip on the connection carrier, the component can furthermore be particularly well cooled.

According to at least one embodiment, the optoelectronic component comprises a carrier. The carrier is formed from or consists of a metallic material, for example. The carrier is or comprises, for example, a leadframe. The component can be contacted in an electrically conductive manner via the carrier.

According to at least one embodiment, the connection carrier is arranged on the carrier. For example, the connection carrier does not protrude beyond the carrier in lateral directions. That is to say that in plan view, the connection carrier overlaps with the carrier, for example completely.

The semiconductor chip is arranged on a top surface of the connection carrier, for example. In this case, an opposite bottom surface of the connection carrier is arranged on the carrier, for example. The bottom surface of the connection carrier is arranged on the carrier over its entire surface, for example, by means of an adhesive layer. The bonding layer provides, for example, a mechanically stable and thermally conductive connection between the connection carrier and the carrier. The adhesive layer can, for example, be electrically conductive or electrically insulating.

Alternatively, the semiconductor chip is arranged on a bottom surface of the connection carrier, for example. In this case, contact elements are arranged between the top surface of the connection carrier and the carrier. The contact elements can, for example, provide an electrically conductive contact between the connection carrier and the carrier.

According to at least one embodiment, the electrically conductive connection electrically conductively connects the semiconductor chip, the connection carrier and the carrier. If the optoelectronic component comprises the plurality of semiconductor chips and the plurality of electrically conductive connections, the electrically conductive connections electrically conductively connect the semiconductor chips, the connection carrier and the carrier.

According to at least one embodiment, the connection carrier is arranged in a cavity of the carrier. For example, the carrier comprises a carrier base and a carrier wall. The carrier wall surrounds the carrier base, for example in places. For example, the carrier wall can protrude beyond the carrier base in a vertical direction such that the carrier wall and the carrier base form a cavity.

The carrier wall is for example structured. In this case, the carrier wall has regions that are spaced apart in lateral directions. The spaced apart regions of the carrier wall have, for example, no direct electrically conductive contact with one another. The regions of the carrier wall surround the carrier base in places, for example. For example, at least one region of the carrier wall is in direct electrically conductive contact with the carrier base. Furthermore, it is possible that at least one further region of the carrier wall is not in direct electrically conductive contact with the carrier base.

The laterally spaced apart regions of the carrier wall have, for example, a triangular, a square, a hexagonal, a round, an oval or an elliptical shape in plan view. Furthermore, it is possible that different regions have a different shape from one another.

According to at least one embodiment, the connection carrier is surrounded by the carrier in lateral directions. For example, the connection carrier is surrounded by the carrier wall in lateral directions. For example, a top surface of the carrier wall is arranged in a common plane with the top surface of the connection carrier.

According to at least one embodiment, the cavity of the carrier is filled with a first cover body, which is electrically insulating. The first cover body embeds the connection carrier, for example. “Embedded” can mean that the connection carrier is partially or completely inside the first cover body and is enclosed by the first cover body on at least a portion of its otherwise exposed outer surface. In this case, the first cover body can be in direct immediate contact with the connection carrier.

Furthermore, it is possible that the structured carrier wall is embedded in the first cover body. For example, side surfaces of the structured carrier wall are completely covered by the first cover body. Alternatively, it is possible that the side surfaces of the structured carrier wall facing away from the connection carrier are freely accessible and thus not covered by the first cover body.

According to at least one embodiment, the first cover body completely covers a side surface of the connection carrier. In this case, the first cover body is in direct contact with the connection carrier. Furthermore, the first cover body terminates flush with the top surface of the connection carrier, for example. Further, the first cover body can terminate flush with the top surface of the carrier wall. For example, a top surface of the carrier base is completely covered by the first cover body, which is not covered by the connection carrier.

According to at least one embodiment, the electrically conductive connection is arranged on a top surface of the carrier, on a top surface of the connection carrier and on a top surface of the first cover body. For example, the electrically conductive connection is in direct contact with the carrier, with the connection carrier and with the first cover body. For example, it is possible that the semiconductor chip is arranged on the electrically conductive connection. For example, the electrically conductive connection is arranged between the semiconductor chip and the connection carrier. For example, the semiconductor chip and the electrically conductive connection are in direct electrically conductive contact.

For example, if the optoelectronic component has the plurality of semiconductor chips and the plurality of electrically conductive connections, the electrically conductive connections can be arranged on a top surface of the carrier, on a top surface of the connection carrier, and on a top surface of the first cover body. For example, the semiconductor chips can be arranged directly on the electrically conductive connections. In this case, one or more electrically conductive connections are associated with each of the semiconductor chips.

According to at least one embodiment, the first cover body is formed at least in places with the electrically insulating material. Further, it is possible that the first cover body is formed with the electrically insulating material.

According to at least one embodiment, the semiconductor chip is embedded in a second cover body. “Embedded” can mean that the semiconductor chip is partially or completely within the second cover body and is enclosed by the second cover body on at least a portion of its otherwise exposed outer surface. In this case, the second cover body can be in direct immediate contact with the semiconductor chip. If the optoelectronic component has the plurality of semiconductor chips, the second cover body embeds all of the semiconductor chips.

For example, the second cover body is arranged on the first cover body. For example, the second cover body completely covers a top surface of the first cover body. Further, the second cover body can completely cover the electrically conductive connection or the plurality of electrically conductive connections. The top surface of the carrier wall can further be completely covered by the second cover body.

Further, the second cover body can be formed with the electrically insulating material at least in places. It is possible that the second cover body consists of the electrically insulating material.

It is possible that the first cover body and the second cover body are formed of or consist the same electrically insulating material. Alternatively, the first cover body and the second cover body comprise different materials from one another. For example, the electrically insulating material of the first cover body is different from the electrically insulating material of the second cover body.

According to at least one embodiment, a plated through-hole is arranged in places on the carrier. For example, the plated through-hole is arranged on at least one of the spaced apart regions of the carrier wall. The plated through-hole is in direct contact with the carrier, for example. The plated through-hole is thus arranged spaced apart from the semiconductor chip in lateral directions, for example. That is to say that the plated through-hole is arranged laterally to the semiconductor chip. A top surface of the plated through-hole is arranged, for example, in a common plane with the top surface of the semiconductor chip.

Furthermore, it is possible that a plurality of plated through-holes are arranged in places on the carrier. In this case, the plated through-holes are each arranged on one of the regions of the carrier wall.

The plated through-holes comprise or consist of, for example, an electrically conductive material. The electrically conductive material is, for example, a metal or a semiconductor material. The electrically conductive material comprises or consists of, for example, silicon, which can be doped or undoped.

According to at least one embodiment, the plated through-holes are embedded in the second cover body. “Embedded” can mean that the plated through-hole is partially or completely within the second cover body and is enclosed by the second cover body on at least a portion of its otherwise exposed outer surface. In this case, the second cover body can be in direct immediate contact with the plated through-hole. If the optoelectronic component has the plurality of plated through-holes, the second cover body embeds all of the plated through-holes.

According to at least one embodiment, the optoelectronic component comprises a further electrically conductive connection. The further electrically conductive connection is formed, for example, with a metal or an electrically conductive adhesive. Furthermore, the further electrically conductive connection can comprise a combination of several metals.

The further electrically conductive connection has, for example, a height in the vertical direction that is between at least 1 μm and at most 15 μm. The height of the further electrically conductive connection is constant within the producing tolerance, in particular over an entire extent of the further electrically conductive connection. The further electrically conductive connection has, for example, a width in lateral directions that is comparatively large compared to the height of the further electrically conductive connection. The width of the further electrically conductive connection can, for example, be greater than the height of the further electrically conductive connection by a factor of 10 or 100 or 1000.

For example, it is possible for the optoelectronic component to have a plurality of further electrically conductive connections. In particular, the component has a plurality of further electrically conductive connections when the component comprises the plurality of semiconductor chips and the plurality of plated through-holes.

According to at least one embodiment, the further electrically conductive connection is arranged on a top surface of the second cover body, on a top surface of the semiconductor chip and on a top surface of the plated through-hole. For example, the further electrically conductive connection is in direct contact with the second cover body, the semiconductor chip and the plated through-hole. In this case, the plated through-hole provides, for example, an electrically conductive connection between the further electrically conductive connection and the carrier.

For example, if the optoelectronic component comprises the plurality of semiconductor chips and the plurality of further electrically conductive connections, the further electrically conductive connections are arranged on the top surface of the second cover body, on the top surface of the semiconductor chips and on the top surface of the plated through-holes.

According to at least one embodiment, the further electrically conductive connection electrically conductively connects the semiconductor chip and the plated through-holes. For example, if the optoelectronic component has the plurality of semiconductor chips, the plurality of plated through-holes and the plurality of further electrically conductive connections, one of the further electrically conductive connections is electrically conductively connected to one of the semiconductor chips and one of the plated through-holes, respectively, and is in direct contact with the associated components.

According to at least one embodiment, contact elements are arranged on a top surface of the connection carrier. The contact elements comprise, for example, an electrically conductive material. For example, the contact elements are formed by solder balls. By means of the contact elements, the connection carrier can be contacted in an electrically conductive manner. In this case, the optoelectronic component has, for example, no carrier. According to this embodiment, the dimensions of the component can advantageously be further reduced in the vertical direction as well as in lateral directions compared to a component described herein which has a carrier.

According to at least one embodiment, the semiconductor chip is arranged on an opposite bottom surface of the connection carrier. In this case, the semiconductor chip is, for example, a flip chip. The chip contact surfaces of the semiconductor chip are attached to the connection carrier in an electrically conductive and mechanically stable manner, for example, by means of a further adhesive layer. The further adhesive layer comprises, for example, a solder material or an electrically conductive adhesive. For example, in this case, the bottom surface of the connection carrier has no electrically conductive connection and no further electrically conductive connection.

According to at least one embodiment, a plated through-hole is arranged on the connection carrier. For example, the plated through-hole is arranged on the bottom surface of the connection carrier. In this case, the plated through-hole can also be embedded in the connection carrier. “Embedded” can mean that the plated through-hole abuts on the connection carrier, lies partially or completely inside the connection carrier and/or is enclosed by the connection carrier on at least a portion of its otherwise exposed outer surface. In this case, the plated through-hole can be in direct immediate contact with the connection carrier.

According to at least one embodiment, the plated through-hole, the semiconductor chip and the connection carrier are embedded in a third cover body. The third cover body is arranged, for example, on the bottom surface of the connection carrier and covers it completely. “Embedded” can mean that the plated through-hole, the semiconductor chip and the connection carrier are each partially or completely within the third cover body and are each enclosed by the third cover body on at least a portion of its otherwise exposed outer surface. In this case, the third cover body can be in direct direct contact with the plated through-hole, the semiconductor chip and the connection carrier.

For example, it is possible that the third cover body completely covers the side surfaces of the plated through-hole, the side surfaces of the semiconductor chip and the side surfaces of the connection carrier.

According to at least one embodiment, the electrically conductive connection is arranged on a top surface of the third cover body, on a top surface of the semiconductor chip and on a top surface of the plated through-hole.

According to at least one embodiment, the third cover body is formed at least in places with the electrically insulating material. Further, it is possible that the third cover body is formed with the electrically insulating material.

According to at least one embodiment, the electrically conductive connection electrically conductively connects the semiconductor chip and the plated through-hole.

According to at least one embodiment, the connection carrier comprises an integrated circuitry. The integrated circuitry is formed by or comprises, for example, an integrated circuit (IC). The integrated circuitry comprises, for example, a control unit, an evaluation unit and/or a control unit. The control unit and the evaluation unit read and check the state of the semiconductor chip, for example.

If the optoelectronic component has the plurality of semiconductor chips, the control unit and the evaluation unit each read and check, for example, the state of an associated semiconductor chip. The control unit can, for example, control the state of an associated semiconductor chip and, for example, turn it on or off.

If the semiconductor chip is formed as a photodetector, the semiconductor chip can be read out, for example, by means of the integrated circuitry, such as the control unit and the evaluation unit.

According to at least one embodiment, the optoelectronic component is surface mountable. If the optoelectronic component comprises, for example, the carrier, the carrier can be electrically conductively contactable from a side facing away from the connection carrier. If the optoelectronic component does not have a carrier, for example, and the contact elements are arranged on the top surface of the connection carrier, the contact elements can be electrically conductively contactable.

According to one embodiment, a cover is arranged on the electrically insulating material. The cover comprises an opening corresponding to an extent in lateral directions of the semiconductor chip. Further, the cover can completely cover the top surface of the plated through-hole. Further, the cover may completely cover the electrically conductive connection. Alternatively, the cover can completely cover the further electrically conductive connection.

For example, the cover is formed with a further matrix material. The further matrix material is for example formed of a plastic, such as a silicone, an epoxy or an epoxy hybrid material. Furthermore, particles, in particular light-reflecting or light-absorbing particles, can be introduced into the further matrix material, for example. The cover advantageously protects the electrically conductive connection and the insulating material from external influences.

If the optoelectronic component has a plurality of semiconductor chips, the cover comprises a plurality of openings. Here, for example, the semiconductor chips are each arranged in an opening. Alternatively, it is possible for electromagnetic radiation from one semiconductor chip at a time to pass through each of the openings.

A method for producing an optoelectronic component is also disclosed. This method is particularly suitable for producing an optoelectronic component described herein. That is to say that an optoelectronic component described herein is producible by the method described or is produced by the method described. All features disclosed in connection with the optoelectronic component are therefore also disclosed in connection with the method and vice versa.

According to at least one embodiment of the method, a connection carrier is provided.

According to at least one embodiment of the method, an optoelectronic semiconductor chip is applied to the connection carrier.

According to at least one embodiment of the method, the semiconductor chip and/or the connection carrier is embedded in an electrically insulating material. The material of the electrically insulating material is, for example, in a flowable form when applied. In this case, the material is cured after application to form the electrically insulating material.

According to at least one embodiment of the method, an electrically conductive connection is applied, which is electrically conductively connected to the semiconductor chip and/or the connection carrier. The electrically conductive connection can be produced, for example, by sputtering and/or deposition, for example electroless or electrodeposition. By applying the electrically conductive connection, a costly wirebonding process can advantageously be dispensed with.

According to at least one embodiment of the method, the electrically conductive connection is arranged in places on the electrically insulating material.

According to at least one embodiment of the method, the connection carrier is embedded in a first cover body. The first cover body comprises, for example, the electrically insulating material.

According to at least one embodiment of the method, the first cover body is produced by means of film-assisted molding.

According to at least one embodiment, the method comprises embedding the semiconductor chip in a second cover body. The second cover body comprises, for example, the electrically insulating material.

According to at least one embodiment of the method, the second cover body is produced by means of film-assisted molding.

In foil assisted molding (FAM), for example, a mold is used which has two mold halves or consists of two mold halves. At least one mold half is preferably lined with a foil. The foil has the task of preventing the electrically insulating material from adhering to the mold. The connection carrier to be overmolded with the carrier, the plated through-hole and/or the semiconductor chip is inserted into a cavity of the mold. The electrically insulating material to be molded around the connection carrier with the carrier, the plated through-hole and/or the semiconductor chip is initially present in solid form, for example. The electrically insulating material to be injected is brought into a liquid form by heating, for example, and injected into the cavity. Subsequently, the electrically insulating material is cured and the connection carrier with the carrier, the plated through-hole and/or the semiconductor chip is demolded.

Alternatively to the film-assisted molding, the electrically insulating material can be applied by means of a mold casting process.

In the following, the optoelectronic component described herein as well as the method described herein will be explained in more detail with reference to embodiments and the accompanying Figures.

They show:

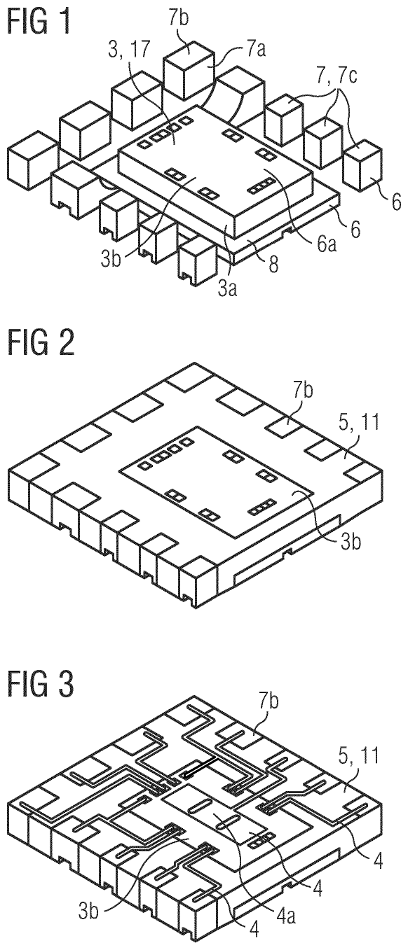

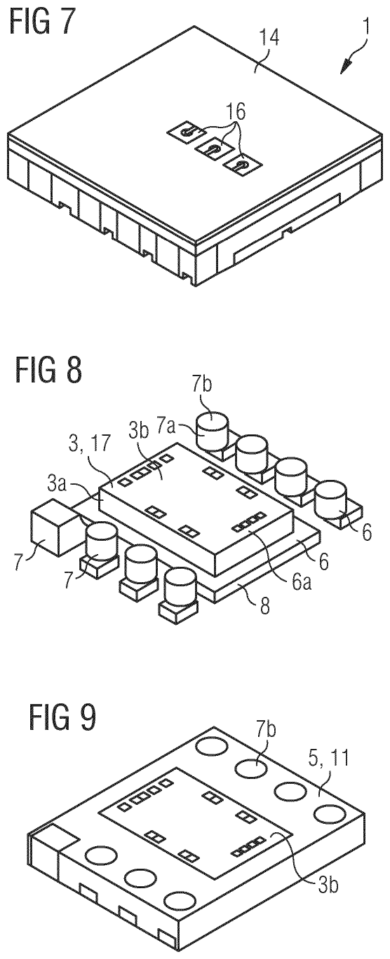

FIGS. 1, 2, 3, 4, 5, 6 and 7 schematic representations of method stages in the process of an optoelectronic component according to an exemplary embodiment,

FIGS. 8, 9, 10, 11 and 12 schematic representations of method stages in the process of an optoelectronic component according to an exemplary embodiment,

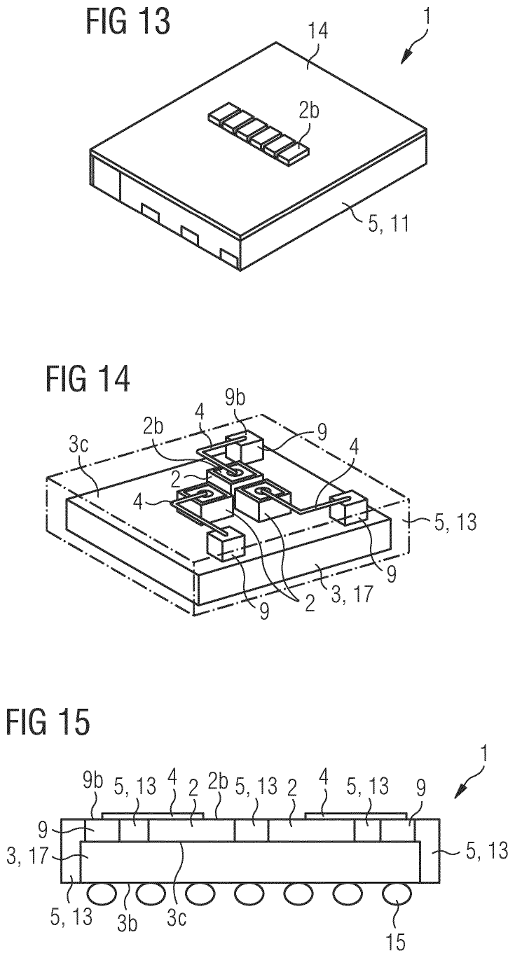

FIG. 13 schematic representation of an optoelectronic component according to an exemplary embodiment,

FIG. 14 schematic representation of an optoelectronic component according to an exemplary embodiment, and

FIG. 15 schematic sectional view of an optoelectronic component according to an embodiment.

Elements that are identical, similar or similar acting are given the same reference signs in the Figures. The Figures and the proportions of the elements shown in the Figures are not to be regarded as true to scale. Rather, individual elements can be shown exaggeratedly large for better representability and/or for better comprehensibility.

The schematic sectional views of FIGS. 1 to 7 show method steps of an exemplary embodiment of a method described herein for producing a radiation-emitting semiconductor component 1.

First, a connection carrier 3 and a carrier 6 are provided, as shown in FIG. 1. The carrier comprises a carrier base 8 and a carrier wall 7. The carrier wall 7 protrudes vertically beyond the carrier base 8 so that the carrier wall 7 and the carrier base 8 form a cavity. The connection carrier 3 is here arranged in the cavity 6a of the carrier 6.

The carrier wall 7 is structured and has regions 7c that are spaced apart in lateral directions. The spaced apart regions of the carrier wall 7c do not have direct electrically conductive contact with one another. The regions of the carrier wall 7c surround the carrier base 8 in places. Two regions of the carrier wall 7c are in direct electrically conductive contact with the carrier base 8. The other regions of the carrier wall 7c are not in direct electrically conductive contact with the carrier base 8. The laterally spaced apart regions of the carrier wall 7c have a square shape in plan view.

According to FIG. 2, an insulating material 5 is introduced into the cavity 6a in a next method step. The electrically insulating material 5 surrounds the connection carrier 3 and the carrier 7 at least in places. A first cover body 11 consists here of the electrically insulating material 5 and embeds the connection carrier 3 and the regions of the carrier wall 7c.

Side surfaces of the connection carrier 3a are completely covered by the first cover body 11. Furthermore, the first cover body 11 terminates flush with a top surface of the connection carrier 3b. Furthermore, the regions of the carrier wall 7c, except for the side surfaces of the structured carrier wall 7 facing away from the connection carrier 3, are completely covered by the first cover body 11. The side surfaces of the structured carrier wall 7a facing away from the connection carrier 3 are freely accessible. The first cover body 11 terminates flush with a top surface of the carrier wall 7b.

In a further step, as shown in FIG. 3, electrically conductive connections 4 are applied to the top surface of the connection carrier 3, the top surface of the regions of the carrier wall 7b and to the first cover body 11 and are in direct contact with the top surface of the connection carrier 3, the top surface of the regions of the carrier wall 7b and the first cover body 11. Since the top surface of the connection carrier 3, the top surface of the regions of the carrier wall 7b and a top surface of the first cover body 11 are arranged in a common plane, the electrically conductive connections 4 extend substantially in lateral directions. “Substantially” means that the common plane can have minor unevenness due to producing tolerances.

At least one of the electrically conductive connections 4 comprises a first mounting surface 4a for a semiconductor chip. In the region of the first mounting surface 4a, the electrically conductive connection 4 has an enlarged extent in lateral directions.

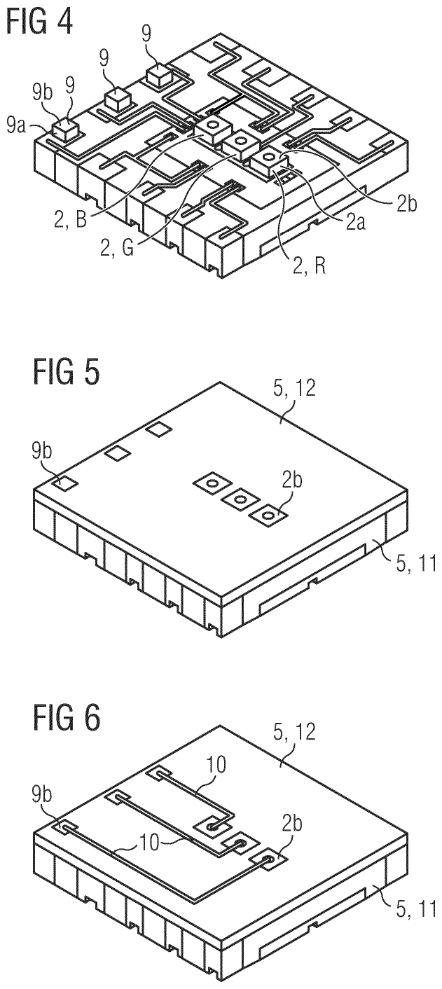

According to FIG. 4, optoelectronic semiconductor chips 2 are arranged on the connection carrier 3. The semiconductor chips 2 are configured, for example, to emit or detect light of different colours. The emitted or detected electromagnetic radiation can, for example, be light of different colours. The semiconductor chips 2 can here be configured to emit or detect electromagnetic radiation, in particular light of red (R), green (G) or blue (B) colour.

The semiconductor chips are here arranged on one of the electrically conductive connection 4, in particular on the first mounting surface 4a. The electrically conductive connection 4 is arranged between the semiconductor chip 2 and the connection carrier 3. The semiconductor chips 2 and the regions of the carrier wall 7c are in direct electrically conductive contact by means of the electrically conductive connections 4.

Furthermore, plated through-holes 9 are arranged in places on the carrier. The plated through-holes 9 are arranged on at least one of the spaced apart regions of the carrier wall 7c and are in direct contact with the carrier wall 7. The plated through-holes 9 are thus arranged at a distance from the semiconductor chips in lateral directions. The plated through-holes 9 are arranged laterally from the semiconductor chips. A top surface of the plated through-holes 9b are arranged in a common plane with the top surface of the semiconductor chips 2b.

As shown in FIG. 5, in a further method step, a second cover body 12 is applied to the first cover body 11. The second cover body 12 completely covers the top surface of the first cover body 11. Furthermore, the second cover body 12 completely covers the electrically conductive connections 4. The top surface of the carrier wall 7b is further completely covered by the second cover body 12.

Furthermore, the semiconductor chips 2 and the plated through-holes 9 are embedded in the second cover body 12. That is to say that the side surfaces of the semiconductor chips 2a and the side surfaces of the plated through-holes 9a are completely covered by the second cover body 12. The top surface of the semiconductor chips 2b, the top surface of the plated through-holes 9b and a top surface of the second cover body 12 lie in a common plane.

According to FIG. 6, in a further method step, further electrically conductive connections 10 are applied to the top surface of the semiconductor chips 2b, the top surface of the plated through-holes 9b and a top surface of the second cover body 12. The further electrically conductive connections 10 are in direct contact with the top surface of the semiconductor chips 2b, the top surface of the plated through-holes 9b and the top surface of the second cover body 12, respectively. The further electrically conductive connections 10 connect the semiconductor chips 2 and the plated through-holes 9 in an electrically conductive manner.

Since the top surface of the semiconductor chips 2b, the top surface of the plated through-holes 9b and the top surface of the second cover body 12 are arranged in a common plane, the further electrically conductive connections 10 extend substantially in lateral directions. “Substantially” means that the common plane can have minor unevenness due to producing tolerances.

In a next method step, a cover 14 is applied to the second cover body 12. The cover comprises an opening 16 for each semiconductor chip 2, through which electromagnetic radiation of the semiconductor chips 2 can pass.

The schematic sectional views of FIGS. 8 to 12 show method steps of an exemplary embodiment of a method described herein for producing a radiation-emitting semiconductor component 1.

In contrast to the method step in connection with FIG. 1, the spaced apart regions of the carrier wall 7c according to FIG. 8 have different shapes in plan view. A region of the carrier wall 7c, which is in direct contact with the base base 8, has a square shape in plan view. The remaining regions of the carrier wall 7c have a round shape in plan view.

According to FIG. 9, as in the exemplary embodiment in connection with FIG. 2, a first cover body 11 is applied. The regions of the carrier wall 7c, which have a round shape in plan view, are here completely surrounded by the first cover body 11. That is to say that side surfaces of the regions of the carrier wall 7c, which have a round shape in plan view, are completely covered by the first cover body 11.

In a next method step, as shown in FIG. 10, electrically conductive connections 4 are applied analogously to the exemplary embodiment in connection with FIG. 3. In contrast to FIG. 3, a second mounting surface 4b for a semiconductor chip is formed by at least two of the electrically conductive connections 4. In the region of the second mounting surface 4b, the associated electrically conductive connections 4 do not have an increased extent in lateral directions.

According to FIG. 11, optoelectronic semiconductor chips 2 are arranged on the connection carrier 3 in a further method step analogous to FIG. 4. The semiconductor chips 2 can be configured here to emit or detect electromagnetic radiation, in particular light of red (R), green (G) or blue (B) colour.

In contrast to FIG. 4, the semiconductor chips are here arranged on at least two of the electrically conductive connections 4, which form the second mounting surface 4b. The at least two electrically conductive connections 4 are arranged between the semiconductor chip 2 and the connection carrier 3.

In this exemplary embodiment, the optoelectronic semiconductor chips 2 are flip chips, each having two contact surfaces on a side facing the connection carrier 3. The contact surfaces are each associated with one of the at least two electrically conductive connections 4 of the mounting surface 4b.

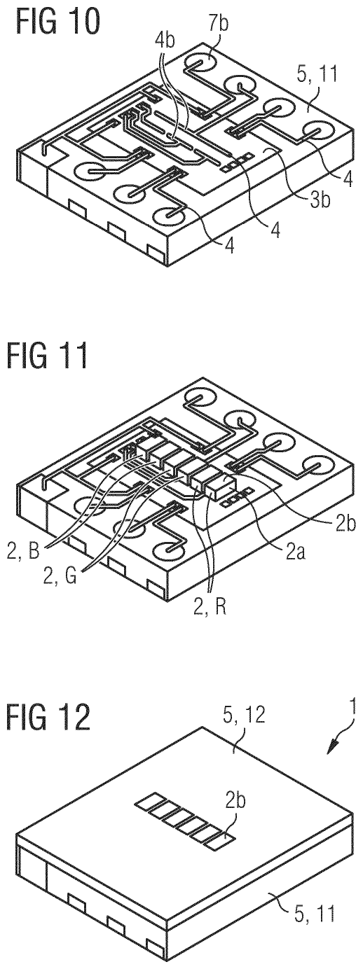

As shown in FIG. 12, in a next step, analogous to the exemplary embodiment in connection with FIG. 5, a second cover body 12 is applied to the first cover body 11. In contrast to the exemplary embodiment in connection with FIG. 5, the optoelectronic component 1 has no plated through-holes 9.

According to FIG. 13, a schematic representation of an optoelectronic component according to an exemplary embodiment is shown.

In contrast to a component 1 in connection with the exemplary embodiment of FIG. 12, the optoelectronic component 1 according to FIG. 13 does not have a second cover body 12. A cover 14 is applied to the first cover body 11. The cover comprises an opening 16 for each semiconductor chip 2, in which the semiconductor chips 2 are arranged.

Referring to FIGS. 14 and 15, schematic representations of an optoelectronic component 1 according to an exemplary embodiment are shown.

In the optoelectronic component 1, as shown in FIGS. 14 and 15, the semiconductor chips 2 are arranged on a bottom surface of the connection carrier 3c. Here, the semiconductor chips 2 are in direct electrically conductive contact with the connection carrier 3. According to this exemplary embodiment, no electrically conductive connections 4 and no further electrically conductive connections 10 are arranged on the bottom surface of the connection carrier 3c.

Furthermore, plated through-holes 9 are arranged on the connection carrier 3. The plated through-hole 9 is arranged on the bottom surface of the connection carrier 3c. According to this exemplary embodiment, the plated through-holes 9 can also be partially located inside the connection carrier 3.

Furthermore, the plated through-holes 9, the semiconductor chips 2 and the connection carrier 3 are embedded in a third cover body 13. The third cover body 13 is arranged on the bottom surface of the connection carrier 9c and covers it completely. Furthermore, the third cover body 13 completely covers the side surfaces of the connection carrier 3a, the side surfaces of the plated through-holes 9a and the side surfaces of the semiconductor chips 2a. A top surface of the plated through-holes 9b, a top surface of the semiconductor chips 2b and a top surface of the third cover body 13 lie in a common plane. Here, the third cover body 13 is made of the electrically insulating material 5.

Electrically conductive connections 4 are arranged on the top surface of the plated through-holes 9b, the top surface of the semiconductor chips 2b and the top surface of the third cover body 13 and are in direct contact with the top surface of the plated through-holes 9b, the top surface of the semiconductor chips 2b and the top surface of the third cover body 13. Since the top surface of the plated through-holes 9b, the top surface of the semiconductor chips 2b and the top surface of the third cover body 13 are arranged in a common plane, the electrically conductive connections 4 extend substantially in lateral directions. “Substantially” means that the common plane can have minor unevenness due to producing tolerances.

The electrically conductive connections 4 each electrically conductively connect a plated through-hole 9 to one of the semiconductor chips 2.

According to FIG. 15, contact elements 15 are arranged on a top surface of the connection carrier 3b. The contact elements 15 are formed here, for example, by solder balls. The contact elements 15 can be used to make electrically conductive contact with the connection carrier 3. In this case, the optoelectronic component 1 does not have a carrier 6.

This patent application claims the priority of the German patent application 10 2019 104 436.7, the disclosure content of which is hereby incorporated by reference.

The invention is not limited to the exemplary embodiments by the description based thereon. Rather, the invention encompasses any new feature as well as any combination of features, which in particular includes any combination of features in the claims, even if this feature or combination itself is not explicitly indicated in the claims or exemplary embodiments.

### REFERENCES

1 optoelectronic component

2 optoelectronic semiconductor chip

2a side surface semiconductor chip

2b top surface semiconductor chip

3 connection carrier

3a side surface of connection carrier

3b top surface of connection carrier

3c bottom surface of connection carrier

4 electrically conductive connection

4a first mounting surface

4b second mounting surface

5 electrically insulating material

6 carrier

6a cavity

7 carrier wall

7a side surface of carrier wall

7b top surface of carrier wall

7c regions of carrier wall

8 carrier base

9 plated through-hole

9a side surface plated through-hole

9b top surface plated through-hole

10 further electrically conductive connection

11 first cover body

12 second cover body

13 third cover body

14 cover

15 contact elements

16 opening

17 integrated circuitry

R red

G green

B blue

1. Optoelectronic component with
an optoelectronic semiconductor chip, which is configured to emit or detect electromagnetic radiation,
a connection carrier, on which the semiconductor chip is arranged,
a carrier, on which the connection carrier is arranged,
an electrically conductive connection, which is electrically conductively connected to the semiconductor chip and/or the connection carrier, and
an electrically insulating material, which surrounds the semiconductor chip and/or the connection carrier at least in places, wherein
the electrically conductive connection is arranged in places on the electrically insulating material, and
the carrier comprises a lead frame.

2. Optoelectronic component according to claim 1, in which the electrically conductive connection electrically conductively connects the semiconductor chip, the connection carrier and the carrier.

3. Optoelectronic component according to claim 2, in which
the connection carrier is arranged in a cavity of the carrier, and
the connection carrier is surrounded by the carrier in lateral directions.

4. Optoelectronic component according to claim 3, in which
the cavity of the carrier is filled with a first cover body, which is formed electrically insulating, and
the first cover body completely covers a side surface of the connection carrier.

5. Optoelectronic component according to claim 1, in which
the electrically conductive connection is arranged on a top surface of the carrier, on a top surface of the connection carrier and on a top surface of a first cover body, and
the first cover body is formed at least in places with the electrically insulating material.

6. Optoelectronic component according to claim 1, in which
the semiconductor chip is embedded in a second cover body.

7. Optoelectronic component according to claim 6, in which
a plated through-hole is arranged in places on the carrier, and
the plated through-hole is embedded in the second cover body.

8. Optoelectronic component according to claim 7 with a further electrically conductive connection, in which
the further electrically conductive connection is arranged on a top surface of the second cover body, on a top surface of the semiconductor chip and on a top surface of the plated through-hole, and
the further electrically conductive connection electrically conductively connects the semiconductor chip and the plated through-hole.

9. Optoelectronic component according to claim 1, in which
contact elements are arranged on a top surface of the connection carrier, and
the semiconductor chip is arranged on an opposite bottom surface of the connection carrier.

10. Optoelectronic component according to claim 1, in which
a plated through-hole is arranged on the connection carrier,
the plated through-hole, the semiconductor chip and the connection carrier are embedded in a third cover body,
the electrically conductive connection is arranged on a top surface of the third cover body, on a top surface of the semiconductor chip and on a top surface of the plated through-hole,
the third cover body is formed at least in places with the electrically insulating material, and
the electrically conductive connection electrically conductively connects the semiconductor chip and the plated through-hole.

11. Optoelectronic component according to claim 1,
in which the connection carrier comprises an integrated circuitry.

12. Optoelectronic component according to claim 1,
in which the optoelectronic component is surface mountable.

13. Method for producing an optoelectronic component with the following steps:
providing a connection carrier,
applying an optoelectronic semiconductor chip on the connection carrier,
embedding the semiconductor chip and/or the connection carrier in an electrically insulating material, and
applying an electrically conductive connection, which is electrically conductively connected to the semiconductor chip and/or the connection carrier, wherein
the electrically conductive connection is arranged in places on the electrically insulating material,
the connection carrier is arranged on a carrier, and
the carrier comprises a lead frame.

14. Method according to claim 13, wherein
the connection carrier is embedded in a first cover body, and
the first cover body is produced by means of film-assisted molding.

15. Method according to claim 13, wherein
the semiconductor chip is covered with a second cover body, and
the second cover body is produced by means of film-assisted molding.

16. Optoelectronic component with
an optoelectronic semiconductor chip, which is configured to emit or detect electromagnetic radiation,
a connection carrier, on which the semiconductor chip is arranged,
a carrier, on which the connection carrier is arranged,
an electrically conductive connection, which is electrically conductively connected to the semiconductor chip and/or the connection carrier, and
an electrically insulating material, which surrounds the semiconductor chip and/or the connection carrier at least in places, wherein
the electrically conductive connection is arranged in places on the electrically insulating material,
the electrically conductive connection electrically conductively connects the semiconductor chip, the connection carrier and the carrier, and
the carrier comprises a lead frame.
